(19) United States
(12) Patent Application Publication
(10) Pub. No.: US 2009/0142166 A1
(43) Pub. Date: Jun. 4, 2009

(54) CONTAINER LID OPENING/CLOSING SYSTEM AND SUBSTRATE PROCESSING METHOD USING THE SYSTEM

(75) Inventors: Toshihiko MIYAJIMA, Tokyo (JP); Hiroshi Igarashi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 12/274,701

(22) Filed: Nov. 20, 2008

(30) Foreign Application Priority Data
Nov. 29, 2007 (JP) 2007-308909

(51) Int. Cl. H01L 21/677

(52) U.S. Cl. 414/217.1; 414/806

(57) ABSTRACT

Provided is an FIMS system in which loading is possible in a manner in which multiple thin pods are vertically stacked together, with an information pad being arranged on an abutment surface of the main body of each pod abutting a door and on the side surface of the door corresponding to the abutment surface. When there is detected a state in which the door is pushed in toward a mini-environment, information imparted to the information pad can be detected by the FIMS system.

### BACKGROUND OF THE INVENTION

1. Field of the Invention

The present invention relates to a form of a so-called FIMS (Front-Opening Interface Mechanical Standard) system that is used when transferring, in a semiconductor manufacturing process or the like, reticles, wafers or the like contained in conveying containers called pods between semiconductor processing apparatuses or the like. More specifically, the present invention relates to an FIMS system, that is, a lid opening/closing system, which simultaneously deals with multiple pods called FOUP (Front-Opening Unified Pods), i.e., thin sealed containers each accommodating several reticles or the like, and which opens and closes the lids of the pods to effect transfer of reticles or the like with respect to the pods, and to a substrate processing method using the system.

2. Related Background Art

Up to now, a semiconductor manufacturing process has been conducted in a so-called clean room in which semiconductor wafers are treated with high cleanliness maintained therein. However, in order to cope with an increase in wafer size and reduce a cost required for maintenance of the clean room, a method of maintaining only the inside of a processing apparatus, the pod (container of wafer to be contained), and a mini-environment for substrate transfer from the pod to the processing apparatus in a highly clean state is employed in recent years.

The pod includes a substantially-cube-shaped main body portion having a rack capable of holding multiple wafers therein in a state where the wafers are separated from one another in parallel and having an opening which is used for putting in/taking out wafers on one of the surfaces constituting an outer surface of the main body, and a cover which closes the opening. A pod in which a surface on which the opening is formed is located not vertically below the pod but on a side surface of the pod (capable of being located in front of the minute space) is generically called a front-opening unified pod (FOUP). The present invention is mainly intended for a structure using the FOUP. Conventionally, from the viewpoint of production efficiency, etc., there have been used pods each accommodating ten or more wafers; nowadays, however, due to an increase in wafer diameter, an increase in the requisite number of processes for each wafer, etc., it has come to be considered more preferable to adopt a method in which several wafers are accommodated in each pod and in which the wafers are supplied to individual apparatuses in smaller lots. Japanese Patent Application Laid-Open No. 2004-262654 discloses in detail such a thin pod dedicated to accommodate several wafers and the handling of the same.

The above-mentioned minute space includes a pod side opening portion opposed to the opening of the pod, a door for closing the pod side opening portion, further opening portion provided on a semiconductor processing apparatus side, and a transfer robot that moves from the pod side opening to the inside of the pod to hold the wafer and passes through further opening on a semiconductor processing apparatus side to transfer the wafer to the semiconductor processing apparatus side. A structure for forming the minute space includes a mount base for supporting the pod so that the opening of the pod is simultaneously opposed to the front surface of the door. The mount base is normally movable back and forth with respect to a door direction by a predetermined distance. When the wafers in the pod are to be transferred to the processing apparatus, the pod is moved in a state where the pod is mounted until the lid of the pod comes in contact with the door. After that contact, the lid is removed from the opening of the pod by the door. With the operations described above, the inside of the pod is connected to the inside of the processing apparatus through the minute space. Subsequently, wafer transfer operation is repeated. A system including the mount base, the door, the pod side opening, a door opening/closing mechanism, a wall which is a part of the minute space including the pod side opening, and the like is generally called a front-opening interface mechanical standard (FIMS) system.

As stated above, conventionally, a construction intended for the handling of a single pod accommodating ten or more wafers has been sufficient. However, in the case of a thin pod as described above, from the viewpoint of reducing the processing time, it is necessary to enable to perform supply of wafers or the like to the minute space through substantially simultaneous use of multiple pods or overlapping the periods during which they are in the mounted state. Further, such handling of wafers can also be applied to conveyance of reticles or the like used in exposure processing or the like. Here, in the case in which multiple pods are to be dealt with, a construction may be adopted in which, from the viewpoint of minimizing the grounding area, multiple pods are vertically stacked together. Japanese Patent Application Laid-Open No. 2000-286319 discloses an apparatus serving as a lid opening/closing system corresponding to such pod arrangement. In this construction, multiple pod side openings as described above are formed vertically, and the doors closing the openings are rotated around an axis extending in the longitudinal direction of the rectangular openings, thereby minimizing the space occupied by the requisite mechanism for opening/closing the doors.

Regarding semiconductor wafers or the like, various processings such as cleaning, film formation, and patterning are performed thereon; thereafter, they are cut in a predetermined size, and fed to the subsequent step as individual semiconductor chips. Usually, wafers or the like accommodated in a single pod are fed to the same processing line; however, depending upon the pod, a processing to be performed halfway through different processing lines may be conducted by the same processing system. In this case, it is necessary to always grasp the history of each pod. As disclosed in Japanese Patent Application Laid-Open No. 2007-142192, conventionally, an information pad indicating the history of a pod is provided on the bottom surface of the pod, and, when the pod is mounted on the FIMS mount base, the information pad is read, thereby distinguishing the pod. The information pad is formed by embedding in one member a pin or the like that can be changed between protrusion in one direction and non-protrusion and providing in the other member a recess allowing selection between a state in which the pin can be accommodated and a state in which the pin cannot be accommodated. The state of the pin or the like is in correspondence with the history of the member in which the pin is embedded, that is, in this case, the pod or the wafers accommodated therein, and the recess can accommodated solely a pin or the like indicating this history, whereby it is possible to reliably execute various processings appropriate to the history of the wafers or the like without involving any mistake.

However, as illustrated in Japanese Patent Application Laid-Open No. 2000-286319, in the case of an FOUP for small lots as described above, a multi-stage arrangement in the vertical direction is effected, and hence it is physically difficult to arrange various constructions on the bottom surfaces of the pods. In particular, in the case of an FIMS in which there is arranged at the minute space opening a so-called tunnel structure proposed for the purpose of preventing mutual influence of dust or the like between the pods vertically arranged, the permissible spaces between the vertically arranged pods are smaller, and such restriction is more conspicuous. That is, it is virtually difficult to embed the information pad as disclosed in Japanese Patent Application Laid-Open No. 2007-142192 in the bottom surface of a conventional pod. Further, even when the information pad is simplified in construction and miniaturized, due to the construction of the information pad, an inappropriate pod is inclined with respect to a flat surface. For example, in the case of a load port (pod lid opening/closing system) for a thin FOUP with a so-called tunnel structure proposed by the present applicant from the viewpoint of controlling dust or the like, even a slight inclination of the pod may lead to apparatus trouble.

### SUMMARY OF THE INVENTION

The present invention has been made in view of the above-mentioned problem in the prior art. It is an object of the present invention to provide a substrate processing method in which various processings are performed on wafers by using a lid opening/closing system in which multiple thin pods are arranged vertically in parallel for processing and which is a pod lid opening/closing system facilitating the grasping of pod history.

In order to solve the above-mentioned problem, the present invention provides a lid opening/closing system for a pod as a container having a container which is provided with a substantially box-like main body capable of accommodating an object to be contained and having an opening in one surface thereof, a lid separable from the main body and closing the opening to form a sealed space together with the main body, and one component of an information pad constituting a pair and indicating a history of the object to be contained through cooperation of a pair of components, the opening being opened by removing the lid from the container to allow insertion/extraction of the object to be contained, including: a container support mechanism supporting the container and capable of moving the container in a predetermined direction; a mini-environment separated from an external space except for an opening of a predetermined size, dust-controlled, and accommodating a mechanism for conveying the object to be contained; a door having a retaining mechanism abutting the lid to retain the lid and another component of the information pad, rotatable around a rotation shaft orthogonal to the predetermined direction and parallel to an extension surface of the object to be contained, and movable between a position in which the opening of the predetermined size is substantially closed and a position in which rotation is effected toward the minute space to open a predetermined opening; a rotation shaft driving mechanism capable of retaining the door via the rotation shaft with a predetermined retaining force so as to maintain the position in which a tunnel is substantially closed and rotating the door around the rotation shaft; and detection means for detecting a change in the position of the door in which the opening of a predetermined size is substantially closed through pressing toward the minute space by the information pad when the container is moved toward the door by the container support mechanism.

Note that it is preferable that the lid opening/closing system described above further include a tunnel having an external space side opening that is an opening on the external space side provided in the vicinity of a position where the container is loaded in the container support mechanism and a mini-environment side opening communicating with the minute space, open on the minute space side, and matched with the opening of a predetermined size, and it is preferable that the door and the rotation shaft be arranged inside the tunnel, and the door position in which the opening of a predetermined size is substantially closed be a position in which the tunnel is substantially closed. Further, in this construction, it is preferable that the rotation shaft driving mechanism further include a fluid cylinder, and the detection means be means that detects the operation of means for driving the rotation shaft.

In order to solve the above-mentioned problem, the present invention provides a lid opening/closing system for the pod as the container having a container which is provided with a substantially box-like main body capable of accommodating an object to be contained and having an opening in one surface thereof, a lid separable from the main body and closing the opening to form a sealed space together with the main body, and one component of an information pad constituting a pair and indicating a history of the object to be contained through cooperation of a pair of components, the opening being opened by removing the lid from the container to allow insertion/extraction of the object to be contained, including: a container support mechanism supporting the container and capable of moving the container in a predetermined direction; a mini-environment separated from an external space, dust-controlled, and accommodating a mechanism for conveying the object to be contained; a tunnel having an external space side opening that is an opening on the external space side provided in the vicinity of a position where the container is loaded in the container support mechanism and a mini-environment side opening communicating with the minute space and open on the minute space side; a door having a retaining mechanism abutting the lid to retain the lid and another component of the information pad, arranged in the tunnel, rotatable around a rotation shaft orthogonal to the predetermined direction and parallel to an extension surface of the object to be contained, and capable of relative movement in the predetermined direction with respect to the container moved by the container support mechanism in a state in which the tunnel is substantially closed while being orthogonal to the extension direction of the tunnel; a rotation shaft driving mechanism capable of retaining the door via the rotation shaft with a predetermined retaining force so as to maintain the position in which the tunnel is substantially closed and rotating the door around the rotation shaft; and detection means for detecting a change in the position of the door in which the tunnel is substantially closed through pressing toward the minute space by the information pad when the container is moved toward the door by the container support mechanism.

In order to solve the above-mentioned problem, the present invention provides a method of processing an object to be contained which is provided with a substantially box-like main body capable of accommodating the object to be contained and having an opening in one surface thereof and a lid separable from the main body and closing the opening to form a sealed space together with the main body, the opening being removed by removing the lid from the container to allow insertion/extraction of the object to be contained, the object to be contained being inserted/extracted into/from the container, a predetermined processing being performed on the object to be contained outside the container, the method using a lid opening/closing system having: a dust-controlled minute space; a conveying mechanism for the object to be contained arranged inside the minute space; a door adapted to substantially close an opening provided in the minute space while maintaining a predetermined retaining force imparted by a drive mechanism and capable of retaining the lid; and a support mechanism supporting the container and driving the container in a predetermined direction, causing the door to retain the lid, the method including: fixing the container to the support mechanism while causing the container to be supported by the support mechanism; driving the support mechanism to cause the lid to abut the door to thereby cause the door to retain the lid; driving the support mechanism and the door relative to each other in the predetermined direction to separate the container and the lid from each other; rotating the lid and the door around a shaft orthogonal to the predetermined direction and contained in an extension surface of the object to be contained to thereby cause the lid and the door to retreat from a drive region for the container; and driving the container in the predetermined direction to arrange the container at an insertion/extraction position for the object to be contained, in which information indicating a history of the objected to be contained is obtained through cooperation of both components of an information pad constituting a pair and arranged distributively on a main body of the container and on the door, and in which a position in which the door is substantially closed is changed to the minute space side against the retaining force of the information pad when the lid is caused to abut the door, the information from the information pad being obtained through detection of the change.

According to the present invention, it is always possible to detect pod history in a lid opening/closing system in which multiple thin pods are arranged vertically in parallel for processing. Thus, it is possible to reliably prevent a pod accommodating wafers which have undergone the wrong processes or which have the wrong history from being erroneously supplied to a predetermined step. Further, according to the present invention, the pin or the like is embedded in the surface of the pod facing the door, and hence, even in the case of detection of an inappropriate pod, the pod is not inclined with respect to the horizontal surface. Thus, even in the above-mentioned load port having a so-called tunnel, the pod is not brought into contact with the tunnel inner wall at the time of detection of the inappropriate pod, thus preventing so-called pod conveyance error, dust generation due to contact, etc.

Further, in the present invention, the history of a pod indicated by the information pad is detected based on an abnormal operation of the door. Thus, it is possible to know the information of the information pad without having to use a large number of sensors required for the respective pins or multiple wirings added to the sensors as in the prior art, in which the detection is effected based not on accommodation/non-accommodation of pins but, for example, on a sensor. Further, according to the present invention, even when the amount of information to be transmitted increases, it is only necessary to increase the number of pins and that of recesses corresponding thereto. Thus, it is also easily applicable to a pod containing wafers or the like that have undergone a complicated process. Further, according to the pin arrangement, the door pushing-in amount, the resultant displacement of the link mechanism, and the expansion/contraction amount of the cylinder vary, and hence when a sensor capable of reading fine displacement is adopted for the so-called pin cylinder sensor, it is possible to transmit more complicated information.

Further, in the present invention, the driving of the door is effected by a so-called fluid cylinder. Further, the force exerted by the fluid cylinder to retain the door is set smaller as compared with the drive force for advancement/retreat of the pod. Thus, even when the pins or the like come into contact with the door surface during movement of the pod, the door is easily pushed toward the minute space according to the set force of the fluid cylinder, and application of an unnecessary or excessive load to the pod or the pod drive mechanism is prevented. Further, when there is adopted a construction in which door movement is detected on the fluid cylinder side, there exists no component inside the tunnel other than the pod and the pod lid, which is moved while in intimate contact with the door; in a construction in which intrusion of dust or the like into the minute space is prevented by, for example, an airflow, there exists nothing that will disturb the airflow, thus further facilitating the cleaning of the environment at the position of the load port or the pod load.

The above and other objects, features, and advantages of the invention will become more apparent from the following detailed description taken in conjunction with the accompanied drawings.

### BRIEF DESCRIPTION OF THE DRAWINGS

FIG. 1A is a schematic side view of a lid opening/closing system according to an embodiment of the present invention and a main portion of a pod mounted on the system;

FIG. 1B is a schematic sectional view taken along the line 1B-1B of FIG. 1A;

FIG. 1C is a schematic view of the construction of FIG. 1A as taken in the direction of the arrow 1C;

FIG. 1D is a schematic view of the construction of FIG. 1A as taken in the direction of the arrow 1D;

FIG. 2A is a diagram similar to FIG. 1A illustrating multiple systems as illustrated in FIG. 1A stuck together, with the main portions of the individual systems being in different states;

FIG. 2B is not a sectional view but a side view of the construction illustrated in FIG. 2A;

FIG. 3A is a diagram similar to FIG. 1A, illustrating an initial state in which a pod 2 illustrated in FIG. 1A is placed on a movable plate 14 of a system 10;

FIG. 3B is a diagram similar to FIG. 1A illustrating how, in the construction illustrated in FIG. 3A, the pod 2 is driven to cause a lid 4 to be held in contact with and retained by a door 15;

FIG. 3C is a diagram similar to FIG. 1A illustrating how, in the construction illustrated in FIG. 1A, the pod 2 temporarily retreats to cause the lid 4 to be separated from a pod main body 2a;

FIG. 3D is a diagram similar to FIG. 1A illustrating how, in the construction illustrated in FIG. 1A, the door 15 rotates to cause the lid 4 and the door 15 to be accommodated in an accommodating space 20;

FIG. 3E is a diagram similar to FIG. 1A illustrating how, in the construction illustrated in FIG. 1A, the pod 2 moves to an insertion/extraction position for a wafer 1 to enable execution of an insertion/extraction operation;

FIG. 4 is a schematic view of a substrate processing apparatus according to an embodiment of the present invention;

FIG. 5 is an enlarged view of a main portion of the construction of the present invention illustrated in FIG. 4; and

FIG. 6 is a diagram similar to FIG. 5 illustrating another embodiment of the present invention.

### DETAILED DESCRIPTION OF THE PREFERRED EMBODIMENTS

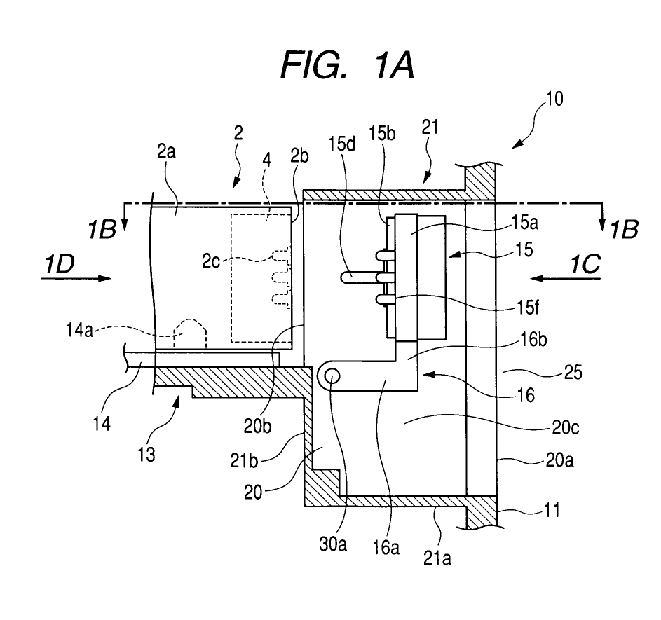

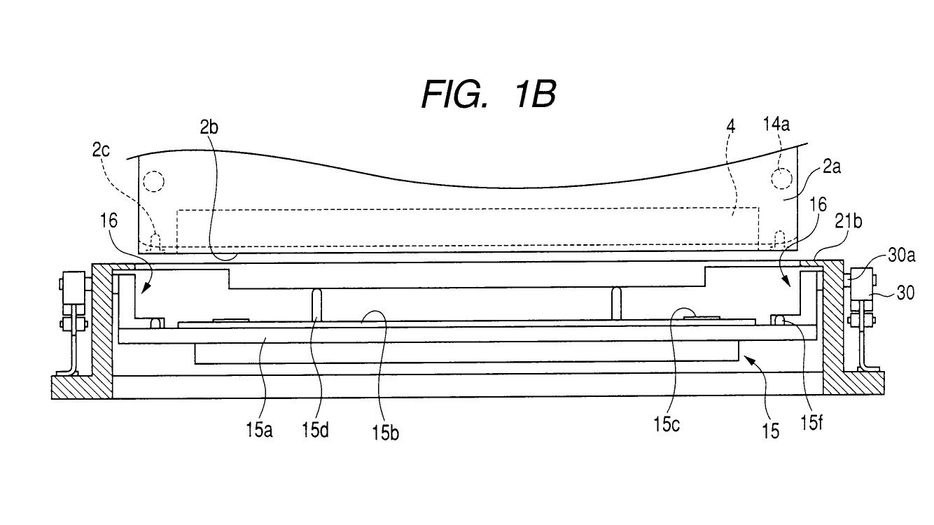

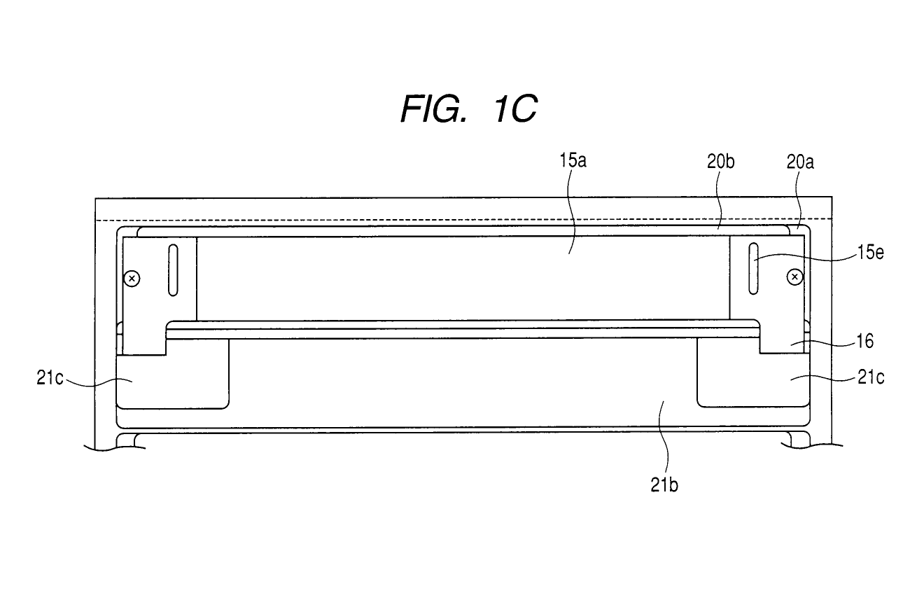

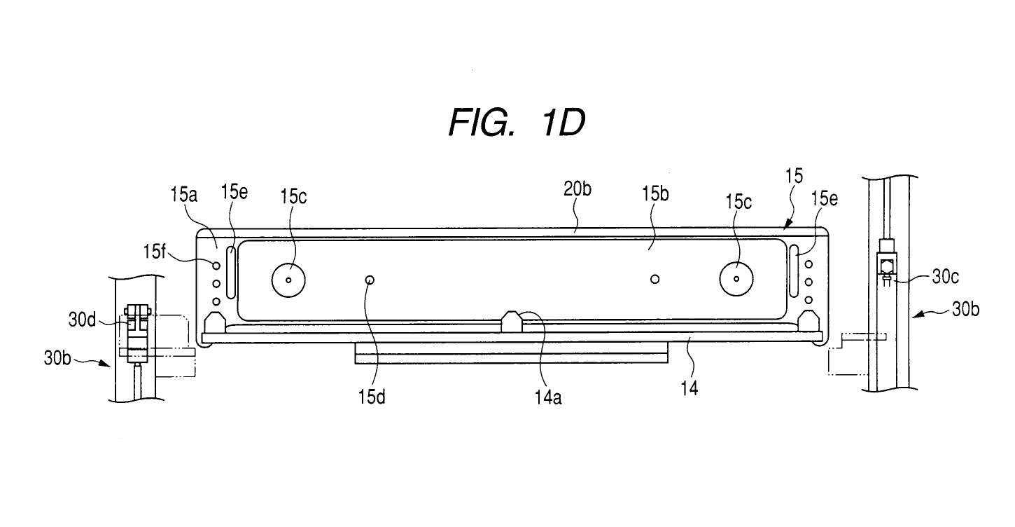

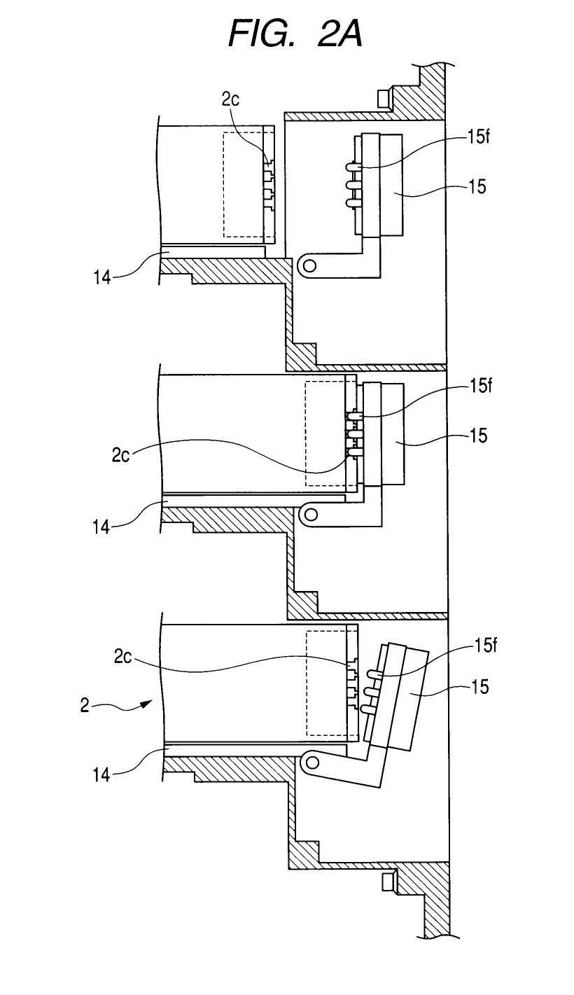

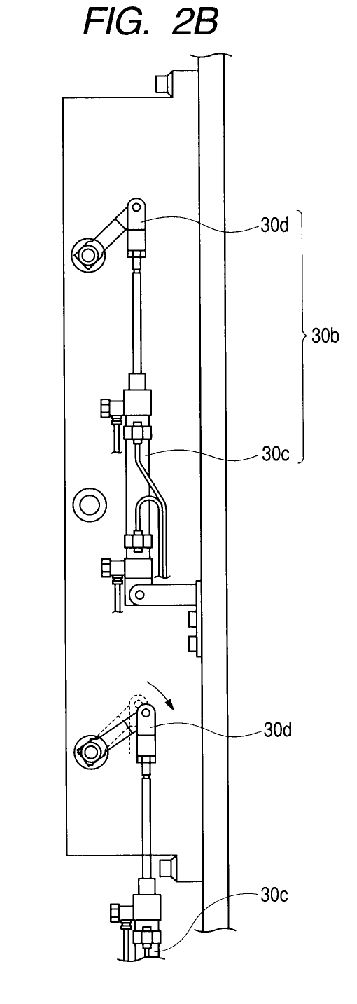

In the following, an embodiment of the present invention is described with reference to the drawings. FIG. 1A is a schematic side view of a part of a thin pod to which the present invention is to be applied and a lid opening/closing system that can deal with each pod individually. While actually multiple systems illustrated in FIG. 1A, etc. are stacked together, in the following, a single system is described for the sake of convenience. FIG. 1B is a sectional view, taken along the line 1B-1B of FIG. 1A, of the system illustrated in FIG. 1A, FIG. 1C is a side view of the same as seen from the direction of the arrow 1C (minute space side), and FIG. 1D is a side view of the same as seen from the direction of the arrow 1D (external space side), with the pod removed. FIG. 2A is a view similar to FIG. 1A illustrating how, in the actual apparatus construction, main portions as illustrated in FIG. 1A are vertically stacked together in three stages. Further, FIG. 2B is a side view of the actual apparatus as seen from the same direction as in FIG. 2A, and the components other than the components to be contained in a tunnel described below such as a movable plate and a pod and a component for driving the system are omitted for the sake of simplification in depiction.

Here, to be described first is a pod mounted on the lid opening/closing system and a wafer to be accommodated in the pod. Formed inside a pod main body 2a of the pod 2 is a space for accommodating one to several wafers to be processed. The pod main body 2a is formed in a thin, substantially box-like configuration having an opening in one of the surfaces existing in the horizontal direction. The pod 2 has a lid 4 for sealing the opening 2b of the pod main body 2a. Arranged inside the pod main body 2a is a shelf (not shown) having multiple stages for vertically stacking together wafers 1 that are held horizontally, and the wafers 1 mounted thereon are accommodated inside the pod 2 at fixed intervals. The wafers 1 correspond to the objects to be accommodated in the present invention, the pod 2 corresponds to the container, the pod main body 2a, which has a basically box-like configuration, corresponds to the main body defined as a body of a substantially box-like configuration, and the opening 2b of the pod 2, which is basically of a rectangular configuration, corresponds to the opening defined as a substantially rectangular opening. At both sides of the opening 2b of the pod main body 2a and in the surface facing a door 15 described below adapted to effect opening of the lid 4 of the like, there are arranged information pad recesses 2c for receiving information pad pins 15f described below. In this embodiment, three recesses are arranged vertically at the side positions. The openings of the information pad recesses 2c can be arbitrarily switched between a closed state and an open state from the outside.

The lid opening/closing system 10 of the present invention includes a mount base 13, a door 15, a tunnel member 21 constituting a tunnel 20, a door opening/closing mechanism 30, and a wall 11 which is a member forming the outer wall of a mini-environment 25 (conveyance chamber described below) communicating with the tunnel. The mount base 13 includes a movable plate 14 on which the pod 2 is actually mounted, which can move the mounted pod toward and away from a first opening 10, and which has a flat surface on its top. A positioning pin 14a is embedded in the flat surface of the movable plate 14, and the positioning pin 14a is fit-engaged with a positioning recess (not shown) provided in the lower surface of the pod main body 2a, whereby the positional relationship between the pod 2 and the movable plate 14 is uniquely determined. The movable plate 14 is connected to a well-known drive mechanism (not shown) including a stepping motor, a ball screw, etc., and in the state in which the pod 2 is mounted thereon, the plate can be stopped at four positions including a loading position for the pod 2 described below, a lid retaining position, a lid removing position, and a wafer insertion/extraction position. In the present invention, the structure including the mount base 13 or the movable plate 14 functions as a container support mechanism or a support mechanism which supports the pod or the like and moves the pod in a predetermined direction.

The tunnel member 21 includes a peripheral wall portion 21a which rises vertically from the wall 11 toward the external space, that is, in the driving direction of the movable plate 14 and which forms a space whose section perpendicular to the rising direction is rectangular, and an end wall portion 21b restricting the external space side opening of the peripheral wall portion 21a. The lateral length of the tunnel 20 formed by the tunnel member 21 (longitudinal length of the opposing surface of the pod 2 when the pod 2 is opposed to the tunnel 20, that is, the horizontal length) is set larger than the longitudinal length of the surface of the pod 2 opposed to the tunnel so that the pod 2 can be accommodated. The tunnel 20 has two openings: a mini-environment side opening 20a and an external space side opening 20b. That is, the tunnel 20 functions as a tunnel which is open in the vicinity of the space in which the pod 2 is mounted (i.e., loaded) on the movable plate 14 and which establishes communication between the external space and the minute space.

The external space side opening 20b has a lateral length corresponding to the lateral length of the tunnel 20 and a longitudinal length set slightly larger than the lateral length of the opposing surface of the pod 2. As a result, the pod 2 can enter the external space side opening 20b. The lateral length of the minute space side opening 20a is determined taking into consideration the width of an L-shaped arm 16 described below to be arranged so as not to interfere with the pod 2, in addition to the lateral length of the above-mentioned tunnel 20 allowing passage of the pod 2. Its longitudinal length is a length large enough to form an accommodation space 20c accommodating the door 15 retaining the lid 4 of the pod 2 and a part of the door opening/closing mechanism arranged inside the tunnel 20 plus a length slightly larger than the longitudinal length of the above-mentioned opposing surface of the pod 2.

The depth of the tunnel 20 (distance from the external space side opening 20b to the minute space side opening 20a) is set based on the relationship between the length of the both linear portions of the L-shaped arm 16 supporting the door 15 mounted below and the lateral length of the pod lid 4 or the lateral length of the door 15. More specifically, the depth is set such that the portion of the door 15 or the lid 4 closest to the minute space side when the door 15 exists at the retracted position (wafer insertion/extraction position) does not protrude into the minute space, and that the opening of the pod 2 at the position where the lid 4 is removed from the pod 2 (lid insertion/extraction position) can exist inside the tunnel 20. An end wall portion 21b restricts the opening to make the size of the external space side opening 20b the above-mentioned one, and its lateral length is determined from the relationship between the size of the opposing surface of the pod 2 and the minute space side opening 20a. The end wall portion 21b determines the above-mentioned space 20c.

The door 15 has a flat-plate-like abutment member 15b capable of opposing the lid 4 of the pod 2 and having an opposing surface substantially similar to the lid 4, and a door main body portion 15a retaining the abutment member 15b and imparting strength to the abutment member. The door main body portion 15a has a longitudinal length smaller than the longitudinal length of the minute space side opening 20a, and eliminates a fear of occurrence of contact with the periphery of the opening at the time of rotation when opening/closing the lid 4. The abutment member 15b is arranged at the longitudinal center of the door main body portion 15a. Arranged on the surface of the abutment member 15b opposed to the pod 2 are an attraction pad 15c adapted to vacuum-attract the lid 4 to retain the same, a positioning pin 15d determining the positional relationship between the lid 4 and the abutment member 15b, and information pad pins 15f that are pins for the information pad. The positioning pin 15d may also serve to retain the lid, in which case it also functions as a so-called latch key. At both sides of the abutment member 15b of the door main body portion 15a, there are formed slits 15e extending through the main body portion from the minute space side surface (back surface) to the external space side surface (front surface) and extending in the lateral direction of the door main body 15c. Further, one end portion (fixing end portion described below) of the L-shaped arm 16 of an L-shaped configuration is connected to both side portions of the abutment member 15b of the door main body portion 15a. The attraction pad 15c functions as a retaining mechanism for the wafer constituting the object to be accommodated together with an evacuation system (not shown) connected thereto and generating an attraction force in the pad.

The information pad pins 15f are arranged on the surface of the door main body portion 15a facing the pod main body 2a and corresponding to the information pad recesses 2c provided in the pod main body 2a when the door main body portion 15a and the pod main body 2a are brought close to each other. In this embodiment, like the information pad recesses 2c, the information pad pins 15f are arranged, three in number, vertically at both sides of the abutment member. In this embodiment, the information pad pins 15f are constantly in the protruding state. However, in view of the relationship with the information pad recesses 2c, it is also possible for the information pad pins 15f to select a state in which the information pad pins 15f are caused to protrude from the door main body portion 15a through operation from the outside or a non-protruding state in which the information pad pins 15f are accommodated in the door main body portion 15a. In this case, regarding the non-protruding state, it does not mean a state in which the information pad pins 15f are completely accommodated in the main body portion. It is only necessary for the information pad pins 15f to be able to set a level at which the information pad pins 15f can suggest, as the information pad, a condition in which a so-called “nor” state can be detected.

The L-shaped arm 16 includes a rotation shaft side linear portion 16a connected to a door opening/closing mechanism 30 via a rotation shaft 30a described below at an end thereof, and a door side linear potion 16b connected to the door main body portion 15a at an end. The end portion of the door side liner portion 16b acts as a fixing end portion fixed to the door main body portion 15a, and the door side linear portion extends parallel to the extension surface of the door main body portion 15a. The rotation shaft 30a extends through the tunnel member 21 and is connected to a drive mechanism main body 30b of the door opening/closing mechanism 30 arranged outside the tunnel member. The drive mechanism main body 30b includes an air cylinder 30c using air serving as the fluid, a link mechanism 30d, etc. (see FIGS. 1D and 2B), and rotates the rotation shaft 30a between predetermined two angles. The rotation shaft 30a is set to be orthogonal to a predetermined direction which is the driving direction of the movable plate 14 and parallel to a surface perpendicular to the pod opening (extension surface of the wafer constituting the object to be accommodated).

In the construction illustrated in FIGS. 2A and 2B in which individual lid opening/closing systems constituting main components are actually stacked together in multiple stages, the thickness of the individual main portions is set to be small, making it difficult to arrange the drive mechanism main bodies in the same side surface with respect to the individual main portions. In view of this, in this embodiment, there is arranged in the surface illustrated in FIG. 2A a drive mechanism main body 30b for an upper stage main portion and a lower stage main portion, and a drive mechanism main body 30b for a middle stage main portion is arranged in a surface opposed to the surface illustrated in FIG. 2A. FIG. 2A illustrates the upper stage main portion in a so-called loading start state in which the pod 2 is placed on the upper surface of the movable plate 14. As illustrated in FIG. 2A in the middle stage main portion, the pod 2 has been driven by the movable plate, and the information pad pins 15f have been fitted into all the information pad recesses 2c, indicating that a proper pod 2 has been supplied to the system. In the lower stage main portion, there is placed a pod indicating that one of the openings of the lower stage information pad recesses 2c is to be closed. Further, the information pad pins 15f have not been fit-engaged, and hence the door 15 is pushed into the minute space by the pod 2.

Here, the retaining force which is supplied by the air cylinder 30c constituting the drive mechanism main body 30b and which is supplied when the door 15 closes the minute space side opening 20a is set weaker than the driving force which is supplied to the movable plate 14 from a drive mechanism (not shown) and which is directed in the direction of the opening 20a of the pod 2. Thus, in the case in which, for example, the openings of the information pad recesses 2c are closed, and in which the forward ends of the information pad pins 15f cannot be fitted into the corresponding information pad recesses 2c, when the system is placed in the state of the lower stage main portion of FIG. 2A, the door 15 is pushed toward the minute space side by the main body portion 2a via the information pad pins 15f to be shifted in position (see the door 15 in the lower stage of FIG. 2A and the drive mechanism main body 30b in the lower stage of FIG. 2B). Through the operation, the link 30d also moves, and through the operation, the air cylinder 30c is changed in the expansion state thereof. An operation detecting function is imparted to the air cylinder 30c, and the air cylinder 30c detects the shift to generate an alarm signal. The alarm signal is transmitted to a control device (not shown), and informing of the conveyance of an improper pod is performed through lighting of a well-known alarm light, generation of a sound signal, etc.

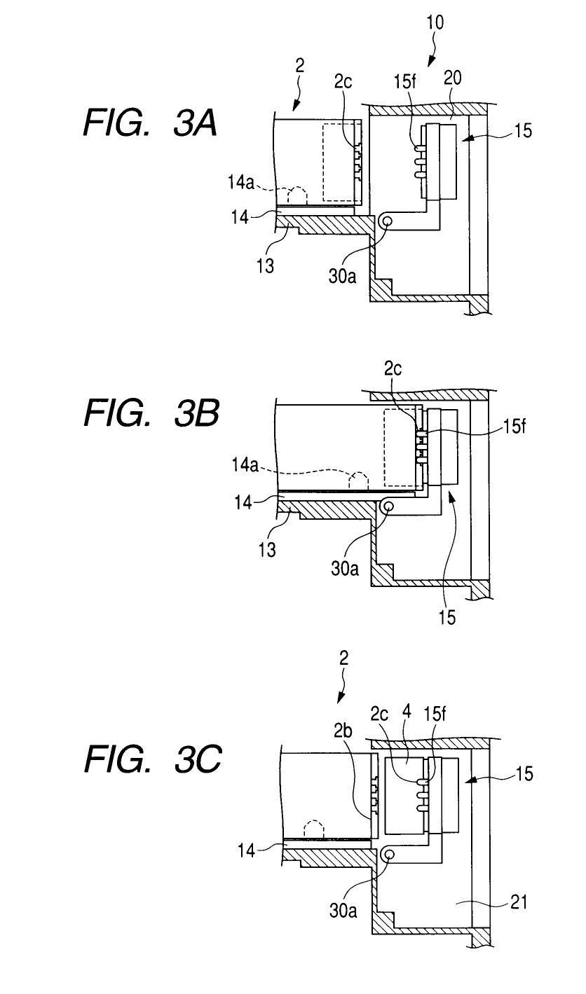

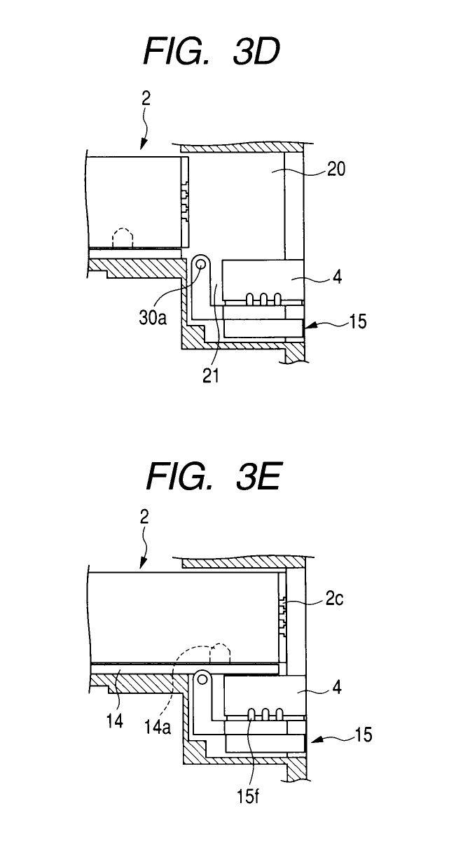

Next, the actual operation of the lid opening/closing mechanism, constructed as described above, is described. The operation is described with reference to FIGS. 3A through 3E illustrating each operation of the opening/closing mechanism main portion in the same manner as FIG. 1A. First, as illustrated in FIG. 3A (or FIG. 1A), the door 15 substantially closes the tunnel 20, and the pod 2 is placed on the movable plate 14 existing at the loading position. After the pod 2 has been placed at a predetermined position on the movable plate 14 through the action of the positioning pin 14a or the like, the movable plate 14 advances in the direction of the door 15 by the drive mechanism (not shown). The movement of the movable plate 14 by the drive mechanism is stopped at the position where the lid 4 closing the pod 2 abuts the attraction pad 15c (FIG. 3B). In this process, the positioning pin 15d is fitted into the positioning recess (not shown) provided in the lid 4, whereby the lid 4 and the door 15 are prevented from coming into contact with each other in an abnormal state. At the same time, the information pad pins 15f provided on the door 15 side are fit-engaged with the information pad recesses 2c provided on the pod 2 side. In the state illustrated in FIG. 3B, the pod accommodating wafers that have undergone a process suited for the system 10 is properly placed, and hence all the information pad pins 15f are fitted into the corresponding information pad recesses 2c, and the door 15 abuts the lid 4 without being shifted from the initial position. After the abutment, the attraction pad 15 executes attraction and retention of the lid 4 by an evacuation mechanism (not shown). FIG. 3B illustrates this state.

When the retention of the lid 4 is effected by the door 15 via the attraction pad 15c, the movable plate 14 retreats to a predetermined lid removal position with the pod 2 placed thereon. Through this retreating movement, the lid 4 retained by the door 15 is separated from the opening 2b of the pod 2. At the time of separation, the pod main body 2a may be attached to the lid 4 due to a seal member (not shown) or due to a difference in pressure between the interior of the pod 2 and the external space. Thus, it is desirable for the pod main body 2a to be fixed to the movable plate 14 by various constructions. In this embodiment, the length of the positioning pin 14a is larger than a certain length to thereby oppose the force applied to the pod main body 2a from the lid 4 at the time of retreat of the movable plate by the positioning pin 14a. In FIG. 3C, the system is at the lid removal position where the movable plate 14 has retreated to a predetermined position, with the lid 4 being separated from the pod main body 2a.

While the movable plate 14 maintains this rest state, the door 15 is rotated by the door opening/closing mechanism 30. The rotation of the door 15 is stopped at the condition illustrated in FIG. 3D, and the door 15 and the lid 4 are accommodated in the accommodating space 21. Subsequently, the movable plate 14 advances, and as illustrated in FIG. 3E, the movable plate 14 is stopped when the pod 2 reaches the wafer insertion/extraction position. In this state, the lid 4, the door 15, etc. are under the pod 2, with the movable plate 14 therebetween. Thus, synergistically with the effect of a down flow generated in the minute space 25, dust or the like adhering to the components such as the lid cannot easily enter the interior of the pod 2. Further, due to the generation of the down flow, the interior of the minute space is maintained at a higher pressure than the external space. Thus, inside the tunnel 20, there is constantly generated an airflow from the minute space side toward the external space side, and the risk of the dust or the like adhering to the lid 4, etc. heading for the opening 2b of the pod 2 is further reduced. Further, in this embodiment, from the viewpoint of attaining the above-mentioned effect, there is maintained an appropriate interval between the inner wall of the tunnel 20, the periphery of the door, and the outer periphery of the pod (interval generating an airflow through the gap without excessively reducing the difference in pressure between the interior of the minute space and the external space and without generating an excessive flow velocity).

In this embodiment, there is used, as means for supplying the drive force for driving the door or for retaining the same at the processing position, an air cylinder 30c, which is a fluid cylinder. The air cylinder has various advantages in use, such as simplicity in device construction, ease with which the environmental cleanliness is maintained, provision of a very weak retaining force, and ease with which synergistic effect with the drive force of the movable plate 14 can be secured due to the ease with which the relatively weak retaining force is adjusted. However, the present invention is not restricted to this form. From the viewpoint of provision of a stronger retaining force or an increase in follow velocity, the air cylinder may be replaced by a cylinder using some other fluid. Further, the above-mentioned construction is not restricted to a fluid cylinder as long as detection of the door drive condition is possible. For example, the feature of the present invention can also be attained by driving the rotation shaft while controlling the torque by a servo mechanism and by detecting the torque.

The information from the information pad is obtained based on the door movement. More specifically, the expansion/contraction of the cylinder is detected by using a so-called cylinder sensor, thereby making a judgment as to the propriety of the pod placed in the system. By adopting this construction, there is no need to provide any protrusions and recesses on the inner peripheral surface, etc. of the so-called tunnel structure of this embodiment. Thus, it is possible to eliminate all the factors hindering laminar flow of gas in the gas flow passage from the interior of the minute space to the external space formed between the tunnel inner peripheral wall and the outer wall of the pod main body. Thus, it is possible to prevent effectively and reliably intrusion of contaminant from the pod main body outer wall into the minute space. However, the present invention is not restricted to this form. For example, it is also possible to detect link operation by an external sensor such as an infrared sensor. In this case also, there is no need to provide a special construction within the tunnel. However, it is necessary to provide a construction for emitting and receiving sensor light. Depending upon the detection accuracy of the sensor, it is possible to detect a minute link change so as to detect, for example, a change other than link displacement according to the information pad. On the other hand, this results in a rather complicated apparatus construction. It is also possible to adopt a construction in which the light of an infrared sensor is directly introduced into the tunnel to detect the door position. While this is not suitable from the viewpoint of maintaining cleanliness, this enables to detect the information from the information pad more directly. For example, it is possible to prevent defective transmission of information due, for example, to a defect in the link mechanism. Thus, it is desirable that the means for detecting the information of the information pad in the present invention be defined comprehensively, inclusive of the above-mentioned construction, as means for detecting the door position in the state in which the pod exists at the position where the pod lid is retained by the door.

This embodiment has been described as applied, as a basic application object of the present invention, to a lid opening/closing system having a so-called tunnel as proposed by the present invention. However, the object of application of the present invention is not restricted to this form. For example, it is also applicable to a system having no tunnel as disclosed in Japanese Patent Application Laid-Open No. 2000-286319. However, in the case of the construction disclosed in Japanese Patent Application Laid-Open No. 2000-286319, when the door movement is to be directly detected, it is necessary to arrange a part or all of the detecting devices of the present invention inside the minute space, in which the number of components existing therein ought to be reduced. Further, in the case in which the link mechanism, etc. exist outside the minute space, adoption of a construction in which the rotation shaft is directly extracted to the outside from the minute space results in an increase in the length of the rotation shaft, and there is a fear of difficulty in maintaining a proper relationship between the drive force of the movable table and the retaining force of the door. Thus, when applying the present invention to the above-mentioned construction, it is desirable to select an appropriate construction and layout from the viewpoint of effecting both the arrangement of the above-mentioned detecting device and the securing of an appropriate retaining force.

In this embodiment, the information pad pins 15f of the information pad are arranged on the door 15 side, and the corresponding information pad recesses 2c are arranged on the pod main body 2a side. However, the present invention is not restricted to this form. It is also possible to arrange the information pad recesses on the door side and to arrange the information pad pins on the pod main body side. The construction of the information pad is not restricted to the one described above, which includes information pad pins and information pad recesses to be fit-engaged with the information pad pins, as long as the construction of the information pad is formed by pairing a pod side structure with a corresponding lid opening/closing system side structure and transmission of information is possible through cooperation of those two structures.

Due to the provision of the lid opening/closing system, constructed as described above, it is always possible to supply a proper pod to a processing device adapted to execute processing in conformity with the history of a pod or of wafers contained in the pod.

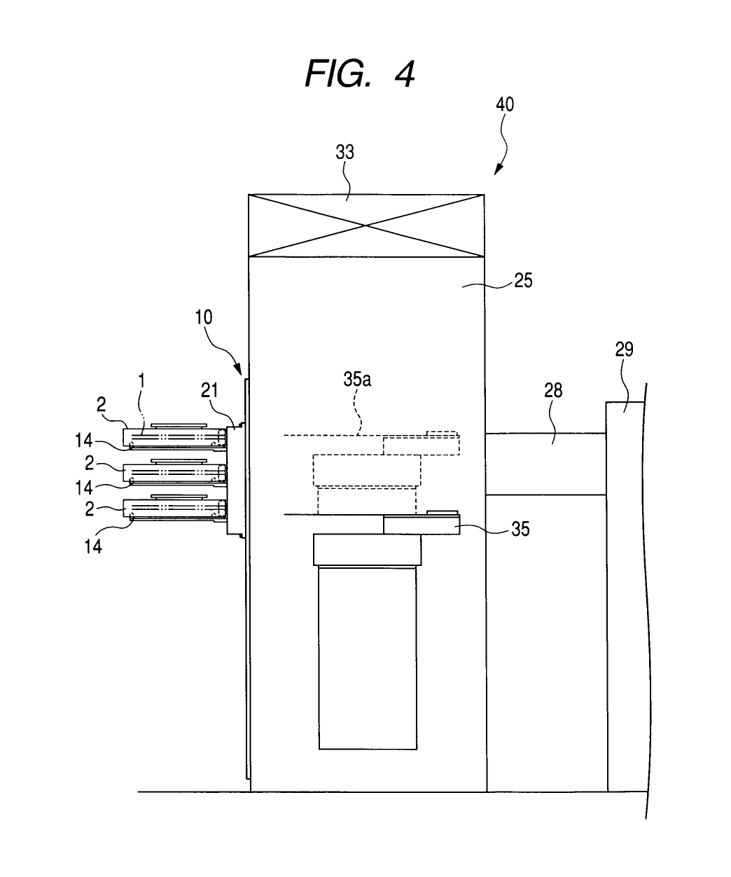

Next, as an embodiment of the present invention, a substrate processing apparatus actually using the above-mentioned lid opening/closing system is described. FIG. 4 is a side view schematically illustrating the construction of a semiconductor wafer processing apparatus (substrate processing apparatus) 40 adapted to the so-called minute space system. The semiconductor wafer processing apparatus 40 includes the load port portion (FIMS system, i.e., the lid opening/closing device) 10, the conveyance chamber (minute space) 25, and a processing chamber 29 as main components. The joint portions between those components are separated by a load port side wall 11 and a processing chamber side communication passage 28. In the conveyance chamber 25 of the semiconductor wafer processing apparatus 40, in order to discharge dust and maintain a high degree of cleanliness, an airflow (down flow) from the upper side to the lower side of the conveyance chamber 25 is generated by a fan filter unit 33 provided in the upper portion of the conveyance chamber. The lower surface of the conveyance chamber 25 is formed of a mesh or the like, whereby there is formed a discharge route for the down flow. Due to the above-mentioned construction, an air controlled in dust, etc. is always introduced into the conveyance chamber 25, and dust or the like existing in the conveyance chamber or brought in from the pod or the like is always carried downwards by the down flow, and discharged.

On the load port portion 10, pods 2 serving as storage containers for silicon wafers or the like (hereinafter simply referred to as wafers) are installed on mount bases 14. In the apparatus of this embodiment, three pods are vertically arranged one upon the other, with each pod 2 containing two wafers 1. As described above, in order to process the wafers 1, a high degree of cleanliness is maintained inside the conveyance chamber 25. Further, inside the conveyance chamber, there is provided a conveyance robot 35 capable of actually retaining wafers as a conveyance mechanism. The conveyance robot 35 can move in the direction in which pods 2 are stacked together (in the vertical direction), and can rotate a robot arm 35a by 360 degrees coaxially. The wafers 1 are transferred between the interior of the pods 2 and the interior of the processing chamber 29 by the conveyance robot 35. The processing chamber 29 usually contains various mechanisms for performing processings such as thin film formation and thin film processing on the wafer surfaces, etc. However, such components are not directly related to the present invention, and hence a description thereof is omitted.

As described above, each pod 2 includes a space for accommodating two wafers 1 constituting the objects to be treated, a box-like pod main body 2a having an opening in one of the surfaces thereof, and a lid 4 for sealing the opening. Inside the pod main body 2a, there is arranged a shelf with multiple stages for stacking the wafers 1 together in one direction, and the wafers 1 placed therein are accommodated inside the pod 2 at a fixed interval. While in the example illustrated herein, the tunnel member 21 has multiple (three systems of) tunnels 20 inside thereof, the above-mentioned tunnel member 21 is simply formed in correspondence with the arrangement of the movable plate 14, and regarding the details thereof, the tunnels 20 are the same as those of the form described above. That is, here, a description and a detailed depiction of the tunnel 20 are omitted since the main construction of the present invention has already been described with reference to the above embodiment and from the viewpoint of facilitating the understanding of the drawing.

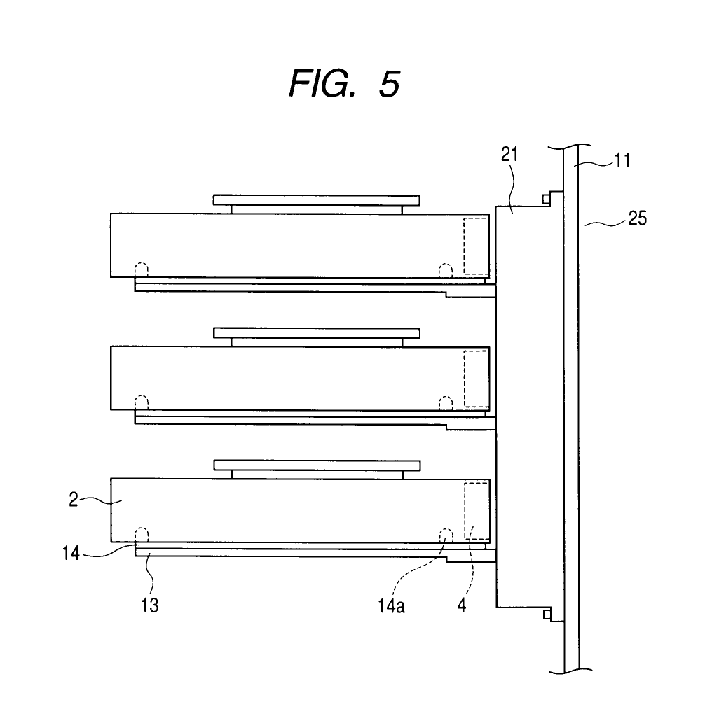

FIG. 5 is an enlarged view of the lid opening/closing system 10 of FIG. 4. In the conventional FIMS system adapted to a pod retaining a large number of wafers, the lid has to be of a size not smaller than a certain level, and hence the door which removes the lid and closes the opening of the minute space cannot but move within the minute space and stop within the space. In the present invention, the door is formed in a thin and narrow plate-like configuration, and hence relative movement is possible between pods in an amount corresponding to the lid width and the door, and the lid and the door are rotated to the exterior of the pod movement region, whereby it is possible to attain a state in which insertion/extraction of wafers into/from the pod is possible. Thus, as illustrated in FIG. 4, the door opening/closing mechanism can be arranged inside a tunnel independent of the minute space 25.

For example, when the robot is driven through combination of movements in three dimensions of X, Y, and Z, there may exist an obstacle in each dimension, making it necessary to move the robot while avoiding the obstacles. In such cases, in order to safely operate the robot, it is necessary to provide a considerably complicated safety circuit. In the present invention, there exists no component protruding into the minute space 25 and causing a problem in the drive in the vertical direction (Z-axis direction) of the robot. Thus, a safety circuit or the like is actually only necessary when the operation of inserting/extracting wafers is to be performed, and hence the circuit formation is substantially facilitated. Further, the minute space 25 contains no components other than the robot 35, and hence there exists no component disturbing the down flow, in particular, no component disturbing the down flow around the pod opening, whereby the discharge efficiency for dust or the like in the down flow is enhanced. Similarly, the possibility of generation of dust from the door or the like due to disturbance of the down flow is reduced. Further, according to the SEMI (semiconductor equipment and materials international) standards used in the semiconductor industry, arrangement of a protrusion around the opening for insertion/extraction of wafers on the minute space side inner wall of the wall forming the minute space is not allowed. In this respect, the present invention is in conformity with the standards.

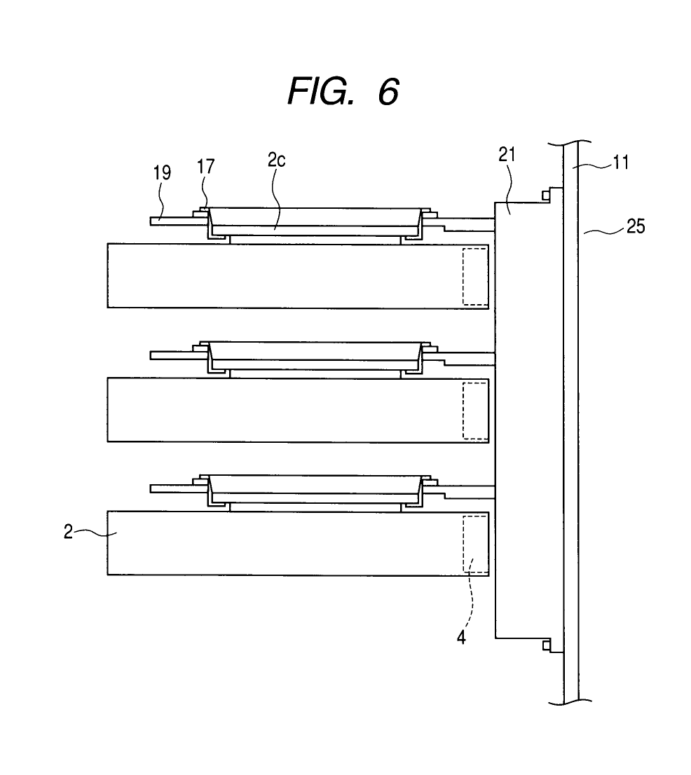

In the above-mentioned embodiment, the movable plate 14 is arranged on the mount base 13, and the pod 2 is placed thereon. However, the present invention is not restricted to this embodiment, and it is also possible to adopt, for example, a system in which the pod 2 is suspended from above. This embodiment is illustrated in FIG. 6, which is similar to FIG. 5. When performing conveyance or the like on the pod 2 through so-called automatic handling, there is used an upper flange 2c fixed to the upper surface of the pod 2, with the conveyance or the like of the pod 2 being effected through suspension of the flange. In this embodiment, the conveyed pod 2 is retained by the suspension member 17, and is transferred together with the suspension member 17 by a suspension member drive mechanism 19.

In this construction, it is possible to eliminate the movable plate 14 of the above-mentioned embodiment, and to avoid the situation in which the plate enters the tunnel 20 together with the pod 2. Thus, it is possible to reduce the accommodation space 20c, which, in the above-mentioned embodiment, has to allow entrance of the plate. However, in the above-mentioned embodiment, it is possible to retain the pod main body 2a on the movable plate 14 with a force that is to some degree against the force applied to the pod main body 2a at the time of separation of the lid 4. In the case of this embodiment, there is a fear of the retaining force for the pod main body 2a at the time of lid separation not being obtained to a sufficient degree. Thus, it may be necessary to form or further add a structure for the purpose. However, since such a structure can also be used, it should be understood that the container support mechanism or the support mechanism of the present invention also includes such a structure.

According to the present invention, there is obtained a lid opening/closing system devoid of component related to the information pad protruding in the vertical direction of the movable plate or protruding into the minute space. In this system, there exists no component protruding in the vertical direction of the movable plate, and hence it is possible to easily form a system in which pods are stacked together in multiple stages in the vertical direction. Further, since there is no component protruding to the pod loading side, it is possible to utilize to a maximum degree the effect of the down flow formed in the minute space. Further, also regarding the conveyance robot for the wafer inserting/extracting operation, there is exists in the minute space no component to be avoided by the robot at the time of movement in the Z-axis direction, of which high speed movement is required, and hence, the preparation of the robot control program is facilitated, and it is possible to easily effect high speed movement.

While the above embodiments have been described as applied to FOUP and FIMS, the application of the present invention is not restricted thereto. The lid opening/closing device of the present invention can be applied to any system as long as it is one which uses a front open type container accommodating multiple objects to be retained and in which the insertion/extraction of the objects to be retained into/from the container is effected through opening/closing of the lid of the container.

As many apparently widely different embodiments of the present invention can be made without departing from the spirit and scope thereof, it is to be understood that the invention is not limited to the specific embodiment thereof except as defined in the appended claims.

This application claims priority from Japanese Patent Application No. 2007-308909 filed Nov. 29, 2007, which is hereby incorporated by reference herein.

What is claimed is:

1. A lid opening/closing system having a container which is provided with a substantially box-like main body capable of accommodating an object to be contained and having an opening in one surface thereof, a lid separable from the main body and closing the opening to form a sealed space together with the main body, and one component of an information pad constituting a pair and indicating a history of the object to be contained through cooperation of a pair of components, the opening being opened by removing the lid from the container to allow insertion/extraction of the object to be contained, comprising:
a container support mechanism supporting the container and capable of moving the container in a predetermined direction;
a mini-environment separated from an external space except for an opening of a predetermined size, dust-controlled, and accommodating a mechanism for conveying the object to be contained;
a door having a retaining mechanism abutting the lid to retain the lid and another component of the information pad, rotatable around a rotation shaft orthogonal to the predetermined direction and parallel to an extension surface of the object to be contained, and movable between a position in which the opening of the predetermined size is substantially closed and a position in which rotation is effected toward a mini-environment to open a predetermined opening;
a rotation shaft driving mechanism capable of retaining the door via the rotation shaft with a predetermined retaining force so as to maintain the position in which the opening of a predetermined size is substantially closed and rotating the door around the rotation shaft; and
detection means for detecting a change in the position of the door in which the opening is substantially closed through pressing toward the minute space by the information pad when the container is moved toward the door by the container support mechanism.

2. A lid opening/closing system according to claim 1, further comprising a tunnel having an external space side opening that is an opening on the external space side provided in the vicinity of a position where the container is loaded in the container support mechanism and a mini-environment side opening communicating with the minute space, open on the minute space side, and matched with the opening of a predetermined size,
wherein the door and the rotation shaft are arranged inside the tunnel, and wherein the door position in which the opening of a predetermined size is substantially closed is a position in which the tunnel is substantially closed.

3. A lid opening/closing system having a container which is provided with a substantially box-like main body capable of accommodating an object to be contained and having an opening in one surface thereof, a lid separable from the main body and closing the opening to form a sealed space together with the main body, and one component of an information pad constituting a pair and indicating a history of the object to be contained through cooperation of a pair of components, the opening being opened by removing the lid from the container to allow insertion/extraction of the object to be contained, comprising:
a container support mechanism supporting the container and capable of moving the container in a predetermined direction;
a mini-environment separated from an external space, dust-controlled, and accommodating a mechanism for conveying the object to be contained;
a tunnel having an external space side opening that is an opening on the external space side provided in the vicinity of a position where the container is loaded in the container support mechanism and a mini-environment side opening communicating with the minute space and open on the minute space side;
a door having a retaining mechanism abutting the lid to retain the lid and another component of the information pad, arranged in the tunnel, and rotatable around a rotation shaft orthogonal to the predetermined direction and parallel to an extension surface of the object to be contained, making it possible to cancel a state in which the tunnel is substantially closed;
a rotation shaft driving mechanism capable of retaining the door via the rotation shaft with a predetermined retaining force so as to maintain the position in which the tunnel is substantially closed and rotating the door around the rotation shaft; and
detection means for detecting a change in the position of the door in which the tunnel is substantially closed through pressing toward the minute space by the information pad when the container is moved toward the door by the container support mechanism.

4. A lid opening/closing system according to claim 3, wherein the rotation shaft driving mechanism includes a fluid cylinder.

5. A lid opening/closing system according to claim 3, wherein the detection means is means that detects the operation of means for driving the rotation shaft.

6. A method of processing an object to be contained for a container which is provided with a substantially box-like main body capable of accommodating the object to be contained and having an opening in one surface thereof and a lid separable from the main body and closing the opening to form a sealed space together with the main body, the opening being removed by removing the lid from the container to allow insertion/extraction of the object to be contained, the object to be contained being inserted/extracted into/from the container, a predetermined processing being performed on the object to be contained outside the container, the method using a lid opening/closing system having:
a dust-controlled minute space;
a conveying mechanism for the object to be contained arranged inside the minute space;
a door adapted to substantially close an opening provided in the minute space while maintaining a predetermined retaining force imparted by a drive mechanism and capable of retaining the lid; and
a support mechanism supporting the container and driving the container in a predetermined direction, causing the door to retain the lid,
the method comprising:
fixing the container to the support mechanism while causing the container to be supported by the support mechanism;
driving the support mechanism to cause the lid to abut the door to thereby cause the door to retain the lid;
driving the support mechanism and the door relative to each other in the predetermined direction to separate the container and the lid from each other;
rotating the lid and the door around a shaft orthogonal to the predetermined direction and contained in an extension surface of the object to be contained to thereby cause the lid and the door to retreat from a drive region for the container; and
driving the container in the predetermined direction to arrange the container at an insertion/extraction position for the object to be contained,
wherein information indicating a history of the objected to be contained is obtained through cooperation of both components of an information pad constituting a pair and arranged distributively on a main body of the container and on the door, and wherein a position in which the door is substantially closed is changed to the minute space side against the retaining force of the information pad when the lid is caused to abut the door, the information from the information pad being obtained through detection of the change.
